(19) United States
(12) Patent Application Publication
(10) Pub. No.: US 2005/0104152 A1
(43) Pub. Date: May 19, 2005

(54) Schottky barrier integrated circuit

(76) Inventors: John P. Snyder, Edina, MN (US); John M. Larson, Northfield, MN (US)

Correspondence Address: Min (Amy) S. Xu, Esq.;DORSEY & WHITNEY LLP, Intellectual Property Department, 50 South Sixth Street, Suite 1500, Minneapolis, MN, 55402-1498, US

(21) Appl. No.: 10/944,627

(22) Filed: Sep. 17, 2004

Related U.S. Application Data
(60) Provisional application No. 60/504,078, filed on Sep. 19, 2003.
(60) Provisional application No. 60/556,046, filed on Mar. 24, 2004.

(51) Int. Cl. H01L 29/76

(52) U.S. Cl. 257/471

(57) ABSTRACT

A Schottky barrier integrated circuit is disclosed, the circuit having at least one PMOS device or at least one NMOS device, at least one of the PMOS device or NMOS device having metal source-drain contacts forming Schottky barrier or Schottky-like contacts to the semiconductor substrate. The device provides a new distribution of mobile charge carriers in the bulk region of the semiconductor substrate, which improves device and circuit performance by lowering gate capacitance, improving effective carrier mobility \overline{μ}, reducing noise, reducing gate insulator leakage, reducing hot carrier effect and improving reliability.

### CROSS-REFERENCE TO RELATED APPLICATION(S)

This application claims the benefit of and priority to U.S. provisional patent application No. 60/504,078, filed Sep. 19, 2003. This application claims the benefit of and priority to U.S. provisional patent application No. 60/556,046, filed Mar. 24, 2004. Each of the above provisional patent applications is incorporated by reference herein in their entirety.

### FIELD OF THE INVENTION

The present invention generally relates to the field of semiconductor integrated circuits (ICs). More particularly, the present invention relates to ICs having Schottky barrier Metal-Oxide-Semiconductor-Field-Effect-Transistors (MOSFETs) including at least one Schottky barrier P-type MOSFETs (PMOS) or N-type MOSFETs (NMOS) and/or Schottky barrier complimentary MOSFETs (CMOS).

### BACKGROUND OF THE INVENTION

One type of transistor known in the art is a Schottky-barrier metal oxide semiconductor field effect transistor (Schottky-barrier MOSFET or SB-MOS). The source and drain electrodes of a SB-MOS device are composed of metal. A Schottky barrier contact is formed at the interface between the metal and a semiconductor substrate. Another type of transistor known in the art is a conventional metal oxide semiconductor field effect transistor (conventional MOSFET). In contrast to the SB-MOS device, the source and drain electrodes of a conventional MOSFET device are composed of impurity doping. Conventional MOSFET devices also have metal silicide regions in the source/drain electrodes. These source/drain metal silicide regions provide ohmic electrical contact to the conductor lines of the conventional MOSFET device, which interconnect the device with other devices on the semiconductor substrate. The metal suicides in the source/drain region of a conventional MOSFET device provide a low resistance contact to the doped source/drain regions and do not contact nor form Schottky barrier contacts to a semiconductor substrate.

One of the important performance characteristics for a MOSFET device is the drive current (I_{d}), which is the electrical current from source to drain when the applied source voltage (Vₛ) is grounded, and the gate (V_{g}) and drain (V_{d}) are biased at the supply voltage (V_{dd}). Drive current is one of the critical parameters that determines circuit performance. For example, the switching speed of a transistor scales as I_{d}, so that higher drive current devices switch faster, thereby providing higher performance integrated circuits.

FIG. 1 shows the relationship of I_{d} 132 for varying V_{g} and V_{d} 131 for a SB-MOS device and a conventional MOSFET device. The curves shown in FIG. 1 illustrate several trends that are well known and are not based on measured data. The I_{d}-V_{d} profile at low V_{d} is the turn-on characteristic. One characteristic of SB-MOS device I_{d}-V_{d} curves is the sub-linear shape for low V_{d} 131, as shown by the solid lines 110,115,120,125,130. For the SB-MOS device, sub-linear I_{d}-V_{d} turn-on is caused by the finite Schottky barrier at the metal source-drain interface to the channel. A conventional MOSFET device provides a linear I_{d}-V_{d} turn-on characteristic 160 at low V_{d}, as shown by the dashed lines 135,140,145,150,155 in FIG. 1. The sub-linear I_{d}-V_{d} turn-on characteristic of the SB-MOS device potentially reduces the effective switching speed of the device when used in an integrated circuit (IC). Sub-linear turn-on has been observed in the literature and referenced as a reason why SB-MOS devices will not be of practicable use in integrated circuits (B. Winstead et al., IEEE Transactions on Electron Devices, 2000, pp. 1241-1246). Industry literature consistently teaches that the Schottky barrier height φ_{b} should be reduced or made less than zero in order to minimize the sub-linear turn-on phenomenon and thus to make SB-MOS device performance competitive with alternative MOSFET device technologies (J. Kedzierski et al., IEDM, 2000, pp. 57-60; E. Dubois et al., Solid State Electronics, 2002, pp. 997-1004; J. Guo et al., IEEE Transaction on Electron Devices, 2002, pp. 1897-1902; K. Ikeda et al., IEEE Electronic Device Letters, 2002, pp. 670-672; M. Tao et al., Applied Physics Letters, 2003, pp. 2593-2595).

Further attempts to develop useful SB-MOS have been reported. For example, U.S. Pat. No. 5,760,449 to Welch proposes a Schottky barrier transistor system having electrically connected N-channel and P-channel MOSFETs, in which source junctions, not drain junctions, of the N- and P-type devices are electrically connected, and which uses a mid-gap chromium silicide to form the Schottky barrier source and drain regions of both N- and P-type devices. In FIG. 8 of Welch, CMOS switching curves are provided. Welch states that an “actual switching curve will be abrupt because of the regenerative nature of a switch.” This suggests that an actual switching curve was not available nor measured from a fabricated circuit. In similar work from Welch, U.S. Pat. No. 5,663,584, U.S. Pat. No. 5,760,449, U.S. Pat. No. 6,091,128, U.S. Pat. No. 6,268,636 B1, and U.S. Pat. No. 6,624,493 B1, Welch proposes various Schottky barrier transistor systems having electrically connected N-channel and P-channel MOSFETs. However, Welch provides no indication that an actual CMOS circuit was developed or fabricated.

Further, Rishton et al. fabricated metal source/drain Schottky barrier NMOS and PMOS device pairs on the same semiconductor substrate (S. A. Rishton et al., J. Vac. Sci. Technol. B, 1997, pp. 2795-2798). As noted by Rishton, tungsten was used as the source/drain material and Si/W was used for the gate material for both the PMOS and NMOS devices. Rishton provides no indication that the Schottky barrier NMOS and PMOS device pairs were electrically connected, and no useful circuit is described or fabricated.

Similarly, U.S. Pat. No. 6,555,879 to Krivokapic proposes a metal source/drain SOI CMOS integrated circuit. As taught by Krivokapic column 7, lines 59-67, a single material is used to form the source/drain regions for both the PMOS and NMOS devices. Krivokapic does not disclose the fabrication or measurement of any useful Schottky barrier circuits.

Despite these attempts, not a single known reference teaches a fabricated integrated circuit having at least one Schottky barrier MOSFET device (Schottky barrier integrated circuit) that has been tested and reported. There is a need in the industry for development of a Schottky barrier integrated circuit, which provides performance, manufacturability and cost benefits as compared to alternative CMOS technologies.

### BRIEF SUMMARY OF THE INVENTION

In one aspect, the present invention provides an integrated circuit, the integrated circuit comprising: at least one NMOS device or PMOS device; wherein at least one of the NMOS devices or PMOS devices is a Schottky barrier MOS (SB-MOS) device with substantial bulk charge transport.

In another aspect of the present invention, a CMOS circuit is provided. The CMOS circuit comprises at least one Schottky barrier NMOS device; at least one Schottky barrier PMOS device, electrically connected to the at least one Schottky barrier NMOS device; wherein at least one of the Schottky barrier NMOS devices or the Schottky barrier PMOS devices provides substantial bulk transport.

In one embodiment of the invention the Schottky barrier NMOS and Schottky barrier PMOS devices each comprise a semiconductor substrate, a gate electrode on the semiconductor substrate, and a source electrode and a drain electrode on the semiconductor substrate. The source and drain electrodes define a channel region having a channel-length and having mobile charge carriers, wherein at least one of the source electrode and drain electrode forms a Schottky or Schottky-like contact to the substrate.

While multiple embodiments are disclosed, still other embodiments of the present invention will become apparent to those skilled in the art from the following detailed description, which shows and describes illustrative embodiments of the invention. As will be realized, the invention is capable of modifications in various obvious aspects, all without departing from the spirit and scope of the present invention. Accordingly, the drawings and detailed description are to be regarded as illustrative in nature and not restrictive.

### BRIEF DESCRIPTION OF THE DRAWINGS

FIG. 1 illustrates example transistor curves for a SB-MOS device and an impurity doped source-drain MOSFET device;

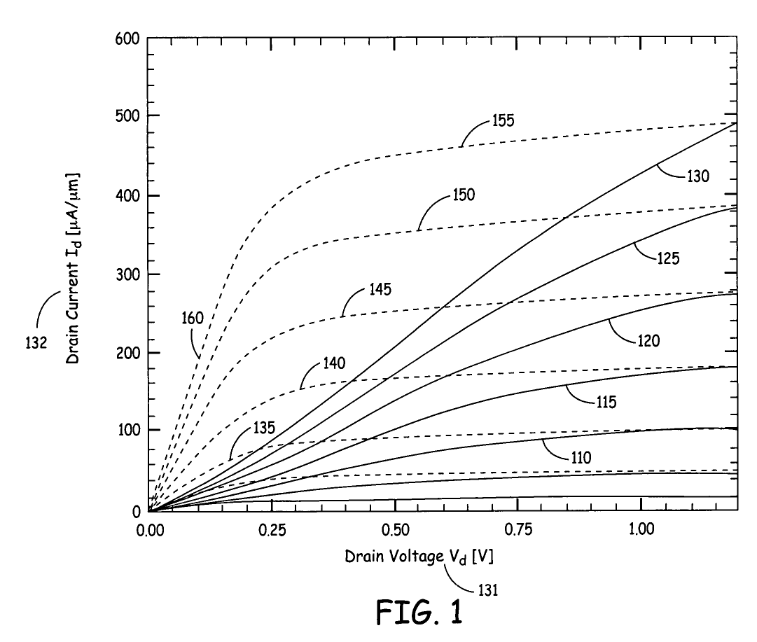

FIG. 2 illustrates a sectional view of an exemplary embodiment of a Schottky-barrier complimentary metal oxide semiconductor field effect transistor (SB-CMOS) of the present invention;

FIG. 3 illustrates an exemplary embodiment of a layout of the Schottky barrier CMOS inverter circuit having Schottky barrier PMOS and Schottky barrier NMOS devices connected in series, in accordance with the principles of the present invention;

FIG. 4 illustrates an exemplary embodiment of a Monte Carlo device simulation of a 25 nm Schottky barrier PMOS device showing the charge carrier distribution in the channel region;

FIG. 5 illustrates an exemplary embodiment of a Monte Carlo device simulation of a 25 nm conventional PMOS device showing the charge carrier distribution in the channel region;

FIG. 6 illustrates an exemplary embodiment of a histogram of charge carrier distribution in the channel regions of a 25 nm Schottky barrier PMOS device and a 25 nm conventional PMOS device, wherein the histogram is shown to a depth of 1.0 nm;

FIG. 7 illustrates an exemplary embodiment of a histogram of charge carrier distribution in the channel regions of a 25 nm Schottky barrier PMOS device and a 25 nm conventional PMOS device, wherein the histogram is shown to a depth of 10.0 nm;

FIG. 8 illustrates an exemplary embodiment of a plot of the current gain of Schottky barrier PMOS devices, wherein the unity current gain is estimated by extrapolation;

FIG. 9 illustrates an exemplary embodiment of a comparison of measured unity current gain for Schottky barrier PMOS devices and conventional PMOS devices, wherein the Schottky barrier PMOS devices provide superior unity current frequency performance; and

FIG. 10 illustrates an exemplary embodiment of a transconductance curve of a Schottky barrier PMOS device according to the present invention.

### DETAILED DESCRIPTION

Overview

In general, the present invention provides an integrated circuit. The integrated circuit is generally comprised of at least one NMOS device or at least one PMOS device; wherein at least one of the NMOS devices or PMOS devices is a Schottky barrier MOS device with substantial bulk charge transport. In one embodiment, the Schottky barrier NMOS and Schottky barrier PMOS devices are each generally comprised of a semiconductor substrate and a gate electrode on the semiconductor substrate. The source electrode and a drain electrode on the semiconductor substrate define a channel region having a channel-length and having mobile charge carriers, wherein at least one of the source electrode and drain electrode forms a Schottky or Schottky-like contact to the substrate.

Of particular advantage, the inventors have discovered that the metal source and drain electrodes provide significantly reduced parasitic series resistance (˜11 Ω-μm) and contact resistance (less than 10⁻⁸ Ω-cm²). The built-in Schottky barrier at the Schottky contacts provides superior control of off-state leakage current. The device substantially eliminates parasitic bipolar action, making it unconditionally immune to latch-up, snapback effects, and multi-cell soft errors in memory and logic. Elimination of bipolar action also significantly reduces the occurrence of other deleterious effects related to parasitic bipolar action such as single event upsets and single cell soft errors. The device of the present invention is easily manufacturable, requiring two fewer masks for source/drain formation, no shallow extension or deep source/drain implants, and a low temperature (<500° C.) source/drain formation process. Due to low temperature processing, integration of new, potentially critical materials such as high K gate insulators, strained silicon and metal gates is made easier.

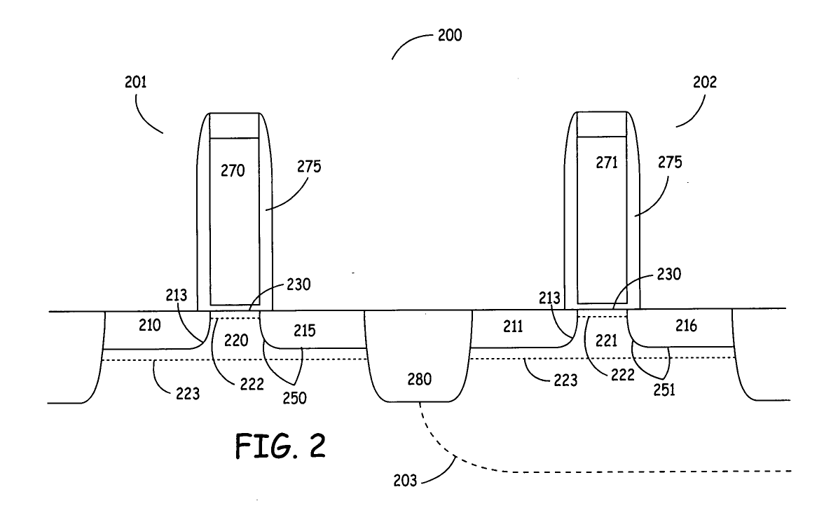

FIG. 2 shows a cross-sectional view of an exemplary embodiment of the invention, as exemplified by a Schottky barrier CMOS circuit (SB-CMOS) 200. This embodiment comprises a Schottky barrier NMOS (SB-NMOS) device 201 and a Schottky barrier PMOS (SB-PMOS) device 202 on a semiconductor substrate 203, the SB-NMOS and SB-PMOS devices electrically connected. One skilled in the art will readily realize that a SB-CMOS circuit can be comprised of many combinations of SB-MOS devices and conventional MOS devices. One such example would include a SB-CMOS circuit comprised of a SB-NMOS device and a conventional PMOS device on a semiconductor substrate, the SB-NMOS and conventional PMOS devices electrically connected.

Throughout the discussion herein, there will be examples provided that make reference to a semiconductor substrate on which an SB-CMOS circuit is formed. The present invention does not restrict the semiconductor substrate to any particular type. One skilled in the art will readily realize that many semiconductor substrates may be used for SB-CMOS circuits including for example silicon, silicon germanium, gallium arsenide, indium phosphide, strained semiconductor substrates, and silicon on insulator (SOI). These substrate materials and any other semiconductor substrate may be used and are within the scope of the teachings of the present invention.

In the SB-CMOS circuit of the present invention, the SB-NMOS and SB-PMOS devices 201,202 comprise source electrodes 210,211 and drain electrodes 215,216, separated by a channel region 220,221 having channel dopants. An insulating layer 230 is located on top of the channel regions 220,221. The channel regions 220,221 are the on-state current-carrying regions of the substrate 203, wherein mobile charge carriers such as holes and electrons flow from the sources 210,211 to the drains 215, 216. A device, such as the SB-NMOS 201 or SB-PMOS device 202, is in the on-state when significant current flows from source to drain due to appropriate device electrical biasing.

For a conventional MOSFET device, the channel region is generally located very close to the insulating layer 230, and does not extend substantially vertically down into the semiconductor substrate 203. Devices having a thin channel region, or inversion layer, are referred to as surface transport devices. For example, the surface transport region or inversion layer is approximately 2 nm thick but more generally between approximately 1 nm to 3 nm thick. In significant contrast to a conventional MOSFET surface transport device, the channel regions 220,221 of the SB-MOS devices 201,202 in the present invention SB-CMOS circuit may extend vertically down substantially into the bulk semiconductor substrate. Substantial mobile charge is located in the bulk semiconductor substrate outside of the surface transport region or inversion layer. For example, substantial mobile charge is located throughout the bulk semiconductor substrate up to a depth approximately 30 nm vertically distant from the inversion layer. In another example, substantial mobile charge is located throughout the bulk semiconductor substrate up to a depth of approximately 50 nm vertically distant from the gate insulator 230 interface to the channel region 220,221. The channel regions 220,221 may contain both surface transport 222 and bulk transport regions 223. For the present invention, SB-NMOS or SB-PMOS devices 201,202 that have substantial mobile charge located in the bulk transport regions 223 are referred to as having substantial bulk charge transport. A device having substantial bulk charge transport is referred to as a substantial bulk transport device. For the present invention, at least one of the SB-NMOS or SB-PMOS devices 201,202 is a substantial bulk transport device. In another embodiment, a substantial bulk charge transport device has at least 10% of the mobile charge located throughout the bulk transport region 223 and outside of the surface transport region 222. In another embodiment, a substantial bulk charge transport device has at least 20% of the mobile charge located throughout the bulk transport region 223 and outside of the surface transport region 222. In yet another embodiment, a substantial bulk charge transport device has at least 20% of the mobile charge located throughout the bulk transport region 223 and outside of the surface transport region 222 that is located within 0 to 2 nm of the gate insulator 230 interface to the channel region 220,221.

Because surface transport MOSFET devices have current flow in the thin inversion layer located immediately below the gate insulator interface to the channel region, the gate insulator interface roughness causes mobile charge carriers to scatter. This scattering mechanism as well as others such as Coulombic scattering effects due to trapped charge in the gate insulator reduce the effective charge carrier mobility, \overline{μ}. In contrast to a surface transport device, the substantial bulk transport device of the present invention provides substantial mobile charge in the bulk semiconductor substrate. Because substantial mobile charge is located more distant from the gate interface, the mobile charge located in the bulk semiconductor substrate is less susceptible to surface and Coulombic scattering effects. For this reason, the effective charge carrier mobility \overline{μ} of a substantial bulk transport device of the present invention will be greater than that of a surface transport device, which will improve device performance.

Referring again to FIG. 2, the sources 210,211 or the drains 215,216 (or both) are composed partially or fully of a metal. Because the sources 210,211 and/or the drains 215,216 are composed in part of a metal, they form Schottky or Schottky-like contacts 250,251 with the substrate 203 and the channel region 220,221. A Schottky contact is formed at the interface between a metal and a semiconductor, and a Schottky-like contact is formed by the close proximity of a metal and a semiconductor, wherein for example, the metal and the semiconductor are separated by approximately 0.1 to 10 nm. The Schottky contacts or Schottky-like contacts or junctions 250,251 may be provided by forming the sources 210,211 and/or the drains 215,216 from metal suicides. Schottky or Schottky-like contact or junctions 250,251 may also be formed by interposing a thin interfacial layer (not shown) between the sources 210,211 and the drains 215,216 and the semiconductor substrate 203. In another exemplary embodiment, the sources 210,211 and the drains 215,216 may also be composed of layered stacks of metals, wherein a first metal is provided in contact with the semiconductor substrate 203, while additional metals may be used to cap or cover the top surface of the first metal. The Schottky (or Schottky-like) barriers 250,251 that exist along the interface of the corresponding metal source/drain 210,211,215,216 and the semiconductor substrate 203 inherently act to confine the charge carriers.

Throughout the discussion herein there will be examples provided that make reference to Schottky and Schottky-like barriers and contacts in regards to IC fabrication. The present invention does not recognize any limitations in regards to what types of Schottky interfaces may be used in affecting the teachings of the present invention. Thus, the present invention specifically anticipates these types of contacts to be created with any form of conductive material or alloy. For example, for the SB-PMOS device, the metal source and drain 211,216 may be formed from any one or a combination of Platinum Silicide, Palladium Silicide, or Iridium Silicide. For the SB-NMOS device, the metal source and drain 210,215 may be formed from a material from the group comprising Rare Earth Silicides such as Erbium Silicide, Dysprosium Silicide or Ytterbium Silicide, or combinations thereof.

Additionally, while traditional Schottky contacts are abrupt, the present invention specifically anticipates that in some circumstances an interfacial layer may be utilized between the silicon substrate and the metal. These interfacial layers may be ultra-thin, having a thickness of approximately 10 nm or less. Thus, the present invention specifically anticipates Schottky-like contacts and their equivalents to be useful in implementing the present invention. Furthermore, the interfacial layer may comprise materials that have conductive, semi-conductive, and/or insulator-like properties. For example, ultra-thin interfacial layers of oxide or nitride insulators may be used, or ultra-thin dopant layers formed by dopant segregation techniques may be used, or ultra-thin interfacial layers of a semiconductor such as Germanium may be used to form Schottky-like contacts, among others.

Referring to FIG. 2, the channel length is the distance from the sources 210,211 to the drains 215,216 electrodes, laterally across the channel region 220,221. Channel dopants are provided in the channel regions 220,221. Indium and Arsenic may be used for the SB-PMOS and SB-NMOS channel dopants respectively. The channel dopant concentration profile typically has a maximum concentration, which is below the source 210,211 and drain 215,216 electrodes, and thus outside of the channel regions 220,221. For the purpose of the present invention, channel dopants are not constrained to be provided exclusively within the channel regions 220,221, but may be found in regions substantially outside of the channel region 220,221 and may have any dopant concentration and concentration profile. In another exemplary embodiment, a retrograde channel implant is used having a peak implant concentration of approximately 1×10¹⁷ cm⁻¹ to 1×10²⁰ cm³ at a depth of approximately 5 nm to 100 nm in the semiconductor substrate and having a concentration of approximately 1×10¹⁵ cm⁻³ to 1×10^{·}cm⁻³ at the gate insulator 230 interface to the channel region 220,221.

The insulating layer 230 is comprised of a material such as silicon dioxide. In another embodiment, a material having a high dielectric constant (high K) is used as the insulating layer 230. Examples of high K materials are those materials having dielectric constants greater than that of silicon dioxide, including for example nitrided silicon dioxide, silicon nitride, and metal oxides such as TiO₂, Al₂₀₃, La₂O₃, HfO₂, ZrO₂, CeO₂, Ta₂O₅, WO₃, Y₂O₃, and LaAlO₃, and the like. A first and second gate electrode 270, 271 are positioned on top of the insulating layer 230, and a thin insulating layer sidewall spacer 275 surrounds the gate electrodes 270,271. The gate electrodes 270,271 may be doped poly silicon, where Boron and Phosphorous dopants are used for the SB-PMOS gate electrode 271 and the SB-NMOS gate electrode 270 respectively. The gate electrodes 270,271 may also be composed of one or more metals. The gate electrodes 270,271 may be comprised of the same metals or different metals. The interface 213 of the source 210,211 and drain 215,216 electrodes to the channel region is located laterally below the spacer 275 and is aligned with the edge of the sides of the gate electrodes 270,271. In another embodiment, the interface 213 of the source 210,211 and drain 215,216 electrodes to the channel region is located laterally below the spacer 275 and partially below the gate electrodes 270,271. In yet another embodiment, a gap is formed between the interface 213 of the source 210,211 and drain 215,216 electrodes to the channel region and the edge of the sides of the gate electrodes 270,271. A field oxide 280 electrically isolates devices from one another, the field oxide for example being a LOCOS or STI field oxide.

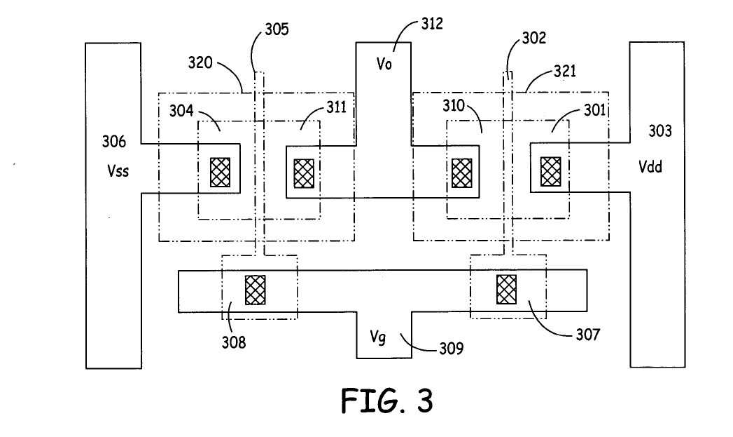

FIG. 3 shows a top view of a preferred exemplary embodiment of the invention, as exemplified by a SB-CMOS inverting circuit and its typical operating and biasing conditions. The source 301 of the SB-PMOS device 302 is connected to a positive supply voltage V_{dd} 303 while the source 304 of the SB-NMOS device 305 is connected to Vₛₛ 306, usually ground. The gate contacts 307 and 308 share a common input electrical connection V_{g} 309 and the drain contacts 310 and 311 share a common output electrical connection Vₒ 312. Well implants 320,321 may or may not be used. If well implants are provided, they may or may not be electrically connected to ohmic contacts. With this exemplary set of biasing conditions, the output voltage Vₒ 312 at the common drain connection of the two devices 302 and 305 depends on the input voltage V_{g} 309 at the gates. When V_{g} 309 is high (usually V_{dd} 303), then the N-type device 305 is on and the P-type device 302 is off. That is, a channel region of the N-type device 305 conducts while a channel region of the P-type device 302 does not conduct. The result being that the output voltage Vₒ 312 changes to the low value Vₛₛ 306. The opposite occurs when V_{g} 309 is low (usually Vₛₛ 306). The N-type device 305 is now off and the P-type device 302 on, and the output voltage Vₒ 312 changes to that of the P-type source, or V_{dd} 303, effectively providing an inverting function.

It will be appreciated by one of ordinary skill in the art that the above SB-CMOS inverter circuit is merely one exemplary way of using complimentary SB-PMOS and SB-NMOS transistors, and that many variations exist for combining SB-PMOS and/or SB-NMOS transistors in an integrated circuit, without departing from the spirit and scope of the present invention. Furthermore, integrated circuits using only one type of Schottky barrier transistor (SB-PMOS-only or SB-NMOS-only) may be advantageously used. Furthermore, an integrated circuit combining at least one SB-PMOS or SB-NMOS transistor with conventional impurity doped PMOS and/or NMOS transistors could be used, without departing from the spirit and scope of the present invention.

Theory and Data

To address the question of whether SB-CMOS technology can be beneficially employed in ICs, the inventors have conducted considerable study with respect to the theory and physics of operation of a SB-MOS device, which is different from the physics of operation of a conventional MOSFET device. As background, Winstead and Ravaioli (B. Winstead et al., IEEE Transactions on Electron Devices, 2000, pp. 1241-1246) used a full-band Monte Carlo device simulator (A. Duncan et al., IEEE Transactions on Electron Devices, 1998, pp. 867-876) to analyze SB-PMOS performance. Winstead simulated a 25 nm SB-PMOS device having a lightly doped substrate with a concentration of 10¹⁵ cm⁻³. He did not simulate any additional retrograde or halo implant in the channel of the device presented in figure four on p. 1243 (B. Winstead et al., IEEE Transactions on Electron Devices, 2000, pp. 1241-1246). Winstead shows therein that mobile charge carriers enter the channel “like a spray with a fairly broad angle.” No quantitative analysis is provided for the location of the mobile charge carriers, but Winstead notes that “carriers are not closely bound to the surface as in a conventional MOSFET because of low doping in the channel.” Winstead does not teach nor quantify the mobile charge distribution in the channel region of a SB-MOS device and does not make a comparison of the charge distribution to that of a conventional MOSFET device. Others have simulated SB-MOS discreet devices and SB-CMOS circuits, such as Connelly, et. al. (D. Connelly et al., EEE Transactions on Electron Devices, 2003, pp. 1340-1345) but have not taught the detailed charge distribution for SB-MOS devices. Therefore, there is a need for more detailed teachings of the charge distribution in a SB-MOS device and how this charge distribution may affect the performance of a SB-MOS device in an integrated circuit.

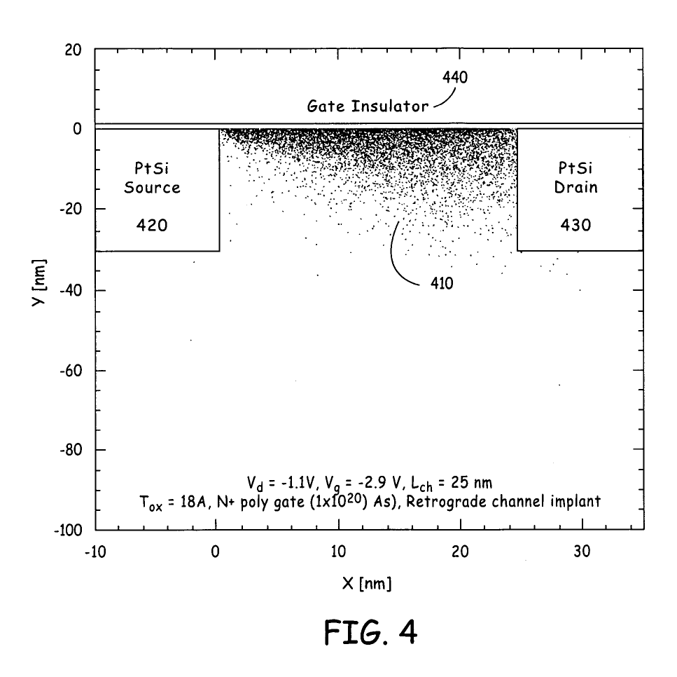

The inventors have accurately quantified the charge distribution in the channel region of SB-MOS and conventional MOSFET devices having more practical channel doping configurations. Simulations were carried out using the Monte Carlo device simulator (A. Duncan et al., IEEE Transactions on Electron Devices, 1998, pp. 867-876). In the present teachings, FIG. 4 shows a snapshot in time for the charge carrier positions in the channel region of a 25 nm channel length SB-PMOS device having a gate oxide thickness of 18 angstroms, and N+ poly gate and biased at Vₛ=0.0V, V_{d}=−1.1V and V_{g}=−2.9V. Unlike the simulations reported by Winstead, the device simulated by the inventors has a retrograde channel implant used to control off-state leakage current. The simulated retrograde channel implant has a channel doping profile that is laterally uniform and varies significantly in the vertical dimension. The channel doping profile had a peak concentration of approximately 2×10¹⁸ cm⁻³ located at a depth of approximately 50 nm in the channel region. The doping concentration at the gate insulator interface to the channel region is 4×10¹⁶ cm^{-3.}

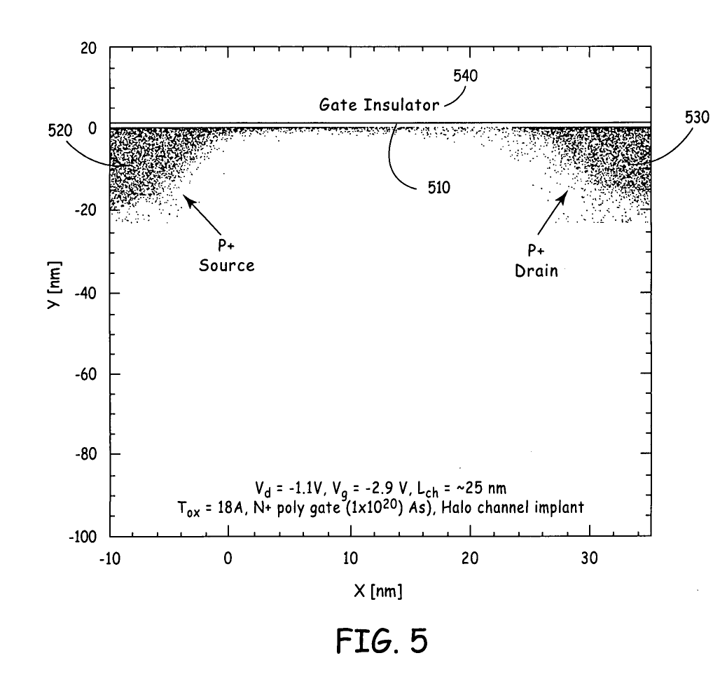

Mobile charge carriers are denoted by the small black symbols 410 located between the source electrode 420 and drain electrode 430 and below the gate insulator 440 for the gate electrode, which is not shown. Each symbol 410 represents one or more charge carriers, depending on a weighting factor (A. Duncan et al., IEEE Transactions on Electron Devices, 1998, pp. 867-876). Similarly FIG. 5 shows a snapshot in time for the charge carrier positions in the channel region of a 25 nm conventional PMOS device having a gate oxide thickness of 18 angstroms, and N+ poly gate and biased at Vₛ=0.0V, V_{d}=−1.1V and V_{g}=−2.9V. Again, mobile charge carriers are denoted by the small black symbols 510 located between the source electrode 520 and drain electrode 530 and below the gate insulator 540 for the gate electrode, which is not shown. For the case of the conventional MOSFET device, mobile charge carriers 510 are also considered in the source 520 and drain 530 regions of the device. From these two figures, it is not obvious quantitatively where the charge is located in the channel, as the resolution of the charge carriers is limited by the pixels in the plots and the resolution of the plot and the plot magnification. One of ordinary skill in the art can not conclude quantitatively from these plots what differences there are in the mobile charge carrier distribution in the channel region, other than to say that for the SB-MOS device, the charge appears more disburse than the conventional MOSFET device. It is not readily apparent from these plots shown in FIG. 4 and FIG. 5 how these charge distribution differences affect the device performance when used in an integrated circuit. Therefore, further teaching is needed to quantify the charge distribution differences and effects on SB-MOS device performance as is described in the following teachings.

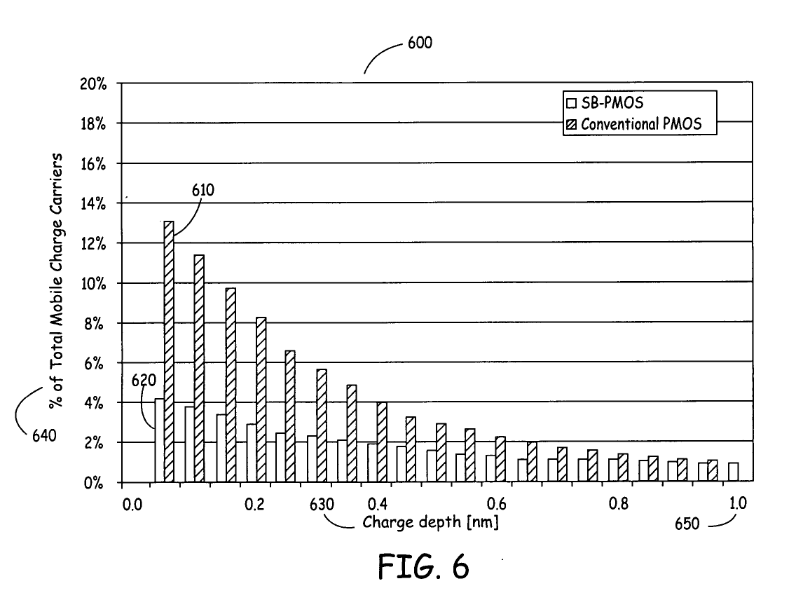

FIG. 6 shows a statistical analysis in histogram format of the charge distribution in the channel region of the conventional PMOS device (hatched bars 610) and the SB-PMOS device (black bars 620), previously described in Paragraphs [039-040]. This analysis takes into account the charge weighting factors, and therefore considers the actual charge density distribution in the channel region. For a given depth 630, the total charge integrated laterally across the channel region is normalized by the total charge in the channel region, and plotted as the percent of total mobile charge carriers 640. In FIG. 6, the charge distribution histogram 600 is only shown to a depth of 1.0 nm 650. The depth 630 is the distance into the channel region vertically below the gate insulator of the device, where a depth of 0.0 nm is the interface of the gate insulator with the channel region of the device.

For the conventional PMOS device, 90% of the charge is located within the first 1.3 nm just below the gate insulator while for the SB-PMOS device, one must integrate to a depth of 10.3 nm below the gate insulator in order to locate 90% of the charge in the channel region. Furthermore, 50% of the charge is located in the first 0.25 nm below the gate insulator for the conventional PMOS device while 50% is located within 1.9 nm of the gate insulator for the SB-PMOS device.

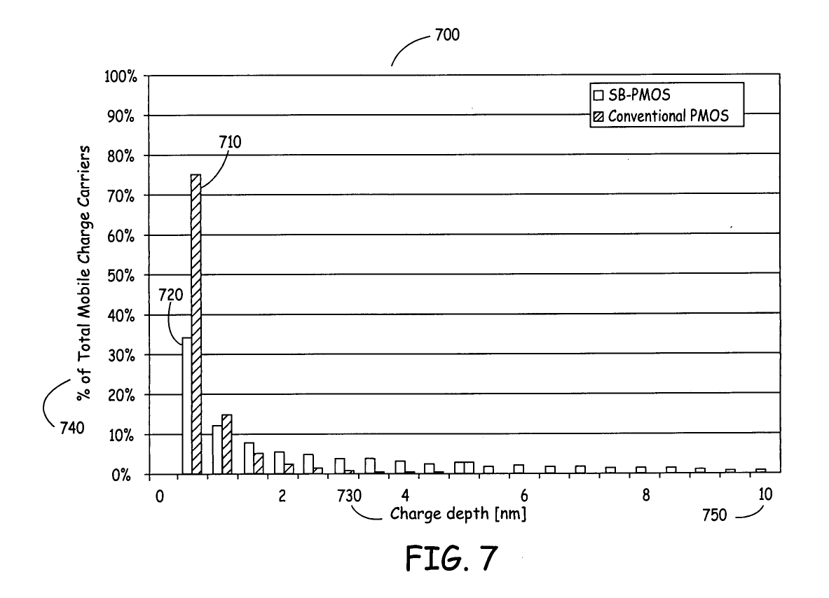

The differences in the charge distribution vertical profile in the channel region become more apparent when considering the histogram distribution to a further depth, as shown in FIG. 7. As with FIG. 6, FIG. 7 shows statistical analysis in histogram format of the charge distribution in the channel region of the conventional PMOS device (hatched bars 710) and the SB-PMOS device (black bars 720). For a given depth 730, the total charge integrated laterally across the channel region is normalized by the total charge in the channel region, and plotted as the percent of total mobile charge carriers 740. In FIG. 7, the charge distribution histogram 700 is shown to a depth 730 of 10.0 nm 750. Again, the depth 730 is the distance in the channel region vertically below the gate insulator of the device, where a depth of 0.0 nm indicates the interface of the gate insulator with the channel region of the device. For the conventional MOSFET device, 74.5% of the charge is found within 0.5 nm of the gate insulator. However, for the SB-PMOS device, only 33.7% of the charge is found within 0.5 nm of the gate insulator. This analysis quantifies the significant difference in how the charge is distributed in the channel region of these two types of devices. This analysis has never been taught or shown in the prior art.

The inventors have conducted similar experiments and analysis as that shown in FIG. 6 and FIG. 7 for a plethora of other device geometries and structures. For example, the thickness of the metal source and drain electrodes for the Schottky barrier device was varied from 5 nm to 30 nm. Counter intuitively, it was found that the mobile charge distribution in the channel region became more disperse as the electrode thickness decreased. For example, considering a surface transport region having a thickness of 2 nm, 59%, 60% and 61% of the mobile charge was located in the bulk transport region for devices having source/drain thicknesses of 30 nm, 15 nm, and 5 nm respectively. Further, the channel length of the Schottky barrier device was varied from 25 to 100 nm. The charge distribution for the 100 nm device continued to show substantial bulk charge transport. For example, considering a surface transport region having a thickness of 2 nm, 59%, 60%, and 42% of the mobile charge was located in the bulk transport region for devices having channel lengths of 25 nm, 50 nm and 100 nm respectively. For all of these simulations, at least 10% of the mobile charge carriers were located throughout the bulk transport region and outside of the surface transport region. In short, the SB-MOS device consistently provided more substantial bulk charge transport compared to the conventional MOSFET.

The effect, if any, of substantial bulk charge transport with respect to the performance of the SB-CMOS circuit of the present invention is considered. For this, one should consider the gate capacitance C_{g}. The switching speed of a CMOS circuit is the speed with which the circuit is capable of switching from the on state to the off state when a voltage change occurs on the input voltage V_{g}. For example, referencing FIG. 3, when the input voltage V_{g} changes from high (V_{dd} 303) to low (Vₛₛ 306), there is a delay before the output voltage Vₒ 312 achieves a new steady state value, high (V_{dd} 303) in this case. The delay time for Vₒ 312 to change determines the switching speed or speed of the device in the circuit, which in part determines the overall speed of operation of the IC. The CMOS circuit switching speed is determined by numerous parameters. One critical parameter is the total effective gate capacitance of the MOSFET device C_{g}. As is known to one of ordinary skill in the art, the intrinsic MOSFET delay (τ) is given by,
τ=C_{g}V_{dd}/I_{d} (1)
where C_{g} is the total MOSFET gate capacitance. The intrinsic switching speed of the device S=1/τ. The SB-MOS literature focuses on I_{d} and the sub-linear turn-on effect, which reduces the I_{d} component of the relationship for τ, thereby increasing τ and decreasing the intrinsic speed S. However, at the same time, due to substantial bulk charge transport as shown in the above teachings, C_{g} is lowered and the intrinsic speed of the device S increases. There has been no prior art teaching regarding the C_{g} component of the τ equation for SB-MOS devices.

Although to date there is no prior art reporting measured circuit performance for circuits fabricated using SB-MOS devices, the inventors have successfully fabricated high performance individual SB-PMOS transistors and devices that can be electrically tested. SB-PMOS devices similar to the device simulated in FIG. 4 have been fabricated and electrically tested. The devices had a channel length of 25 nm, a 1.8 nm pure SiO₂ gate insulator, an N+ poly gate, and Platinum Silicide source/drain electrodes. A first SB-PMOS device having a lightly doped substrate of 1×10¹⁵ cm⁻³ and no additional channel doping was fabricated and tested. At V_{dd}=−1.1V, the on current for the device was measured to be 624 μA/μm and the off current was 6140 nA/μm, resulting in an on/off current ratio of 102.

A second SB-PMOS device was fabricated and tested that included a retrograde Arsenic channel implant having a peak implant concentration of 2×10¹⁸ cm⁻³ at a depth of approximately 50 nm in the channel region. The Arsenic channel implant had a concentration of approximately 4×10¹⁶ cm⁻³ at the gate insulator interface to the channel region. At V_{dd}=−1.1V, the on current for the device was measured to be 460 μA/μm and the off current was 168 nA/μm, resulting in an on/off current ratio of 2738. Although the device was not optimized and the performance can be substantially improved with integration optimization, it has on- and off-currents that nearly meet the requirements of the ITRS roadmap (C. International Technology Roadmap for Semiconductors 2003 Edition Process Integration Devices and Structures, 2003, pp. 11-13) for high performance logic devices having a gate length of 25 nm. Furthermore, this illustrates how a relatively simple retrograde channel implant provides an effective means for controlling off-state leakage current for SB-MOS devices. For example, for the fabricated devices, the retrograde channel implant reduced off-state leakage current from 6140 to 168 μA/μm while reducing the on-state leakage current by a smaller factor from 624 to 460 μA/μm, resulting in a factor of 26.8 improvement in the on/off current ratio. A retrograde channel implant would not suffice to control off-state leakage current of a similar conventional MOSFET device having a channel length of 25 nm. The device simulated in FIG. 4 is very similar to the second device fabricated and electrically tested having the retrograde channel implant. These Monte Carlo simulations and subsequent statistical analysis demonstrate that this fabricated device exhibits substantial bulk charge transport.

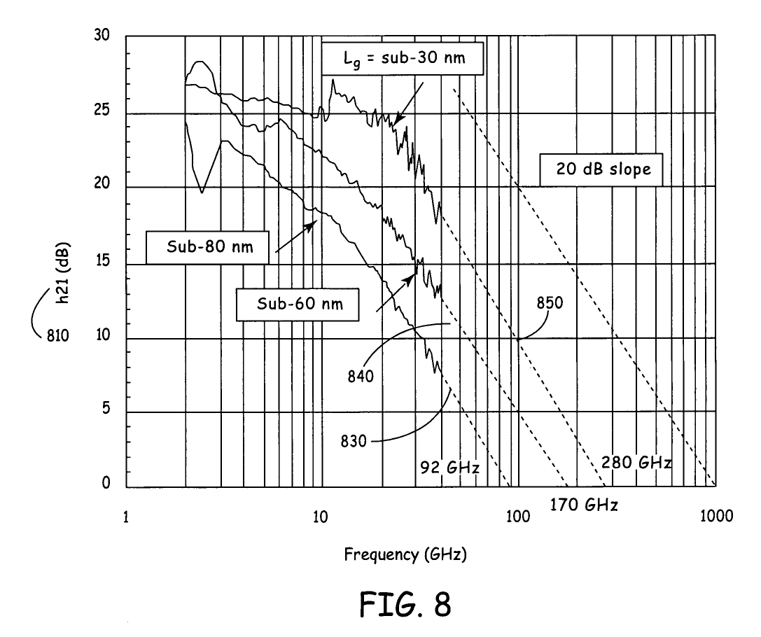

As described in cross-referenced provisional patent application Ser. No. 60/504,078, on-wafer, scattering parameters (S-parameters) were measured up to 40 GHz using a network analyzer and the RF results are shown in FIG. 8. The current gain parameter |h21| 810 is plotted as a function of frequency 820 for devices having a gate length of approximately 75 (830), 55 (840) and 25 nm (850). These devices had a 1.8 nm pure SiO₂ gate insulator, an N+ poly gate, and Platinum Silicide source/drain electrodes. The devices had no retrograde channel implant. Extrapolation of |h21| 810 to 0 dB provides an estimate of the unity current gain frequency, or cutoff frequency f_{T}. The devices with gate lengths of approximately 75 nm (830) and 55 nm (840) had extrapolated f_{T} values of 92 and 170 GHz respectively. The shortest gate length device with approximately 25 nm gate length (850) had extrapolated f_{T} values of 280 GHz. To the best of our knowledge, this is the highest f_{T} reported to date for silicon MOS transistors.

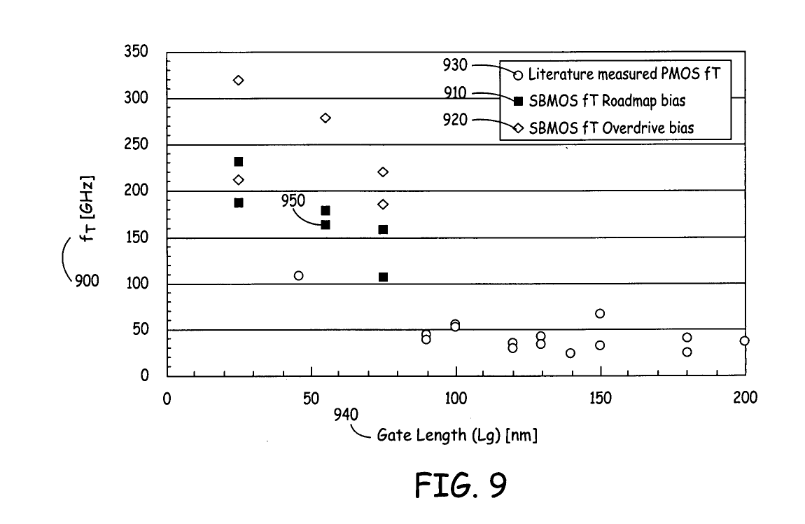

Additional S-parameter data was measured up to 110 GHz. Measurements were made at standard bias conditions and at overdriven bias conditions on devices having a retrograde channel implant and otherwise the same device parameters as those described above. These devices had a retrograde Arsenic channel implant having a peak implant concentration of 1×10¹⁸ cm⁻³ at a depth of approximately 50 nm in the channel region. The Arsenic channel implant had a concentration of approximately 2×10¹⁶ cm⁻³ at the gate insulator interface to the channel region. The standard bias conditions were based on the International Technology Roadmap for Semiconductors for devices having gate lengths of 25 nm, 55 nm and 75 nm (C. International Technology Roadmap for Semiconductors 2001 Edition Process Integration Devices and Structures, 2001, pp. 7; C. International Technology Roadmap for Semiconductors 2002 Update Process Integration Devices and Structures, 2002, pp. 31-32; C. International Technology Roadmap for Semiconductors 2003 Edition Process Integration Devices and Structures, 2003, pp. 11-13). Overdriven bias conditions were conditions in which either V_{d} or both V_{d} and V_{g} were increased above the standard bias conditions through a range of bias points. FIG. 9 summarizes the SB-PMOS f_{T} 900 standard bias measurements 910 and overdriven bias measurements 920 and compares the data with those of conventional PMOS devices 930 on silicon substrates (V. Ferlet-Cavrois et al., IEEE Electron Device Letters, 1998, pp. 265-267; J. N. Burghartz et al., IEEE Transaction on Electron Devices, 2000, pp. 864-870; H. S. Momose et al., IEEE Transaction on Electron Devices, 2001, pp. 1165-1174; N. Zamdmer et al., 2004 Symposium on VLSI Technology Digest of Technical Papers, 2004, pp. 98, 99) as a function of gate length 940. It is clear from FIG. 9 that the SB-PMOS devices as utilized in the present invention provide superior unity current gain frequency performance compared to the conventional PMOS data. For example, the 55 nm L_{g} SB-PMOS device, at standard bias condition has an f_{T} of 164-178 GHz while the interpolated f_{T} for conventional PMOS devices at an L_{g} of 55 nm is approximately 70-80 GHz. The SB-PMOS device provides a factor of approximately 2.05-2.54 higher f_{T} at the same gate length without overdriving the device. When the SB-PMOS device is overdriven, then the 55 nm L_{g} SB-PMOS device provides an estimated f_{T} of 280 GHz, or an improvement over the conventional PMOS device of a factor of approximately 3.5 to 4.0.

The cutoff frequency f_{T} is related to the transconductance (gₘ) and gate capacitance (C_{g}) of a MOSFET device according to the equation:

$${f}_{T} = \frac{{g}_{m}}{2 π {C}_{g}} \qquad ( 2 )$$

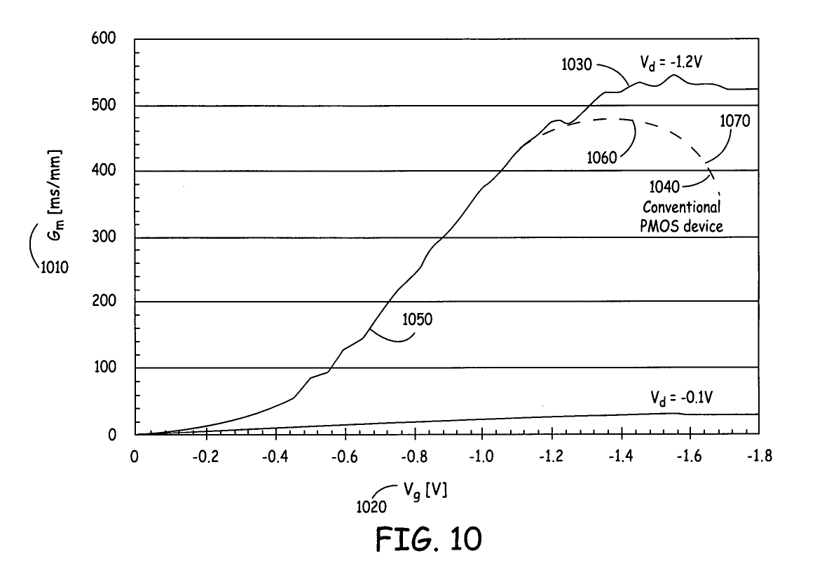

There are therefore two dominant factors causing the high f_{T} measurements for the SB-PMOS devices: high transconductance and/or low gate/source capacitance. Referencing FIG. 10, the transconductance gₘ 1010 for a fabricated and tested SB-PMOS device is shown as a function of gate bias V_{g} 1020. The gₘ curve 1030 was measured at the standard bias conditions for a L_{g}=55 nm SB-PMOS device, for which f_{T} was also measured and reported in FIG. 9. Referencing FIG. 9, the f_{T} for this device (950) is measured to be 164 GHz at a bias of V_{dd}=−1.2V. Referencing FIG. 10, the gₘ for this device (950) is 528 mS/mm at V_{dd}=−1.2V. This is an average gₘ for a PMOS device, and is not sufficiently high to explain the factor of two increase in f_{T} as compared to conventional PMOS devices of similar gate lengths. The only other likely explanation for the high f_{T} is a significant reduction in C_{g}. As noted previously, substantial bulk transport provides a means for reducing C_{g}. For the SB-PMOS device, substantial bulk transport reduces C_{g} significantly, thereby causing improved f_{T} performance. In summary, the high f_{T} data supports the conclusion that the SB-PMOS devices of the present teaching exhibit substantial bulk charge transport.

Referencing FIG. 10, further experimental evidence is provided demonstrating substantial bulk charge transport of the mobile charge carriers in the SB-PMOS device of the present teachings. An example gₘ curve 1040 has been added to the experimental data curve 1030. The curve 1040 illustrates a typical gₘ curve for a conventional PMOS device. The gₘ curve 1040 is not based on measured data and is provided for illustration purposes only. As is well known, the gₘ curve for a conventional PMOS device increases 1050, saturates 1060, and then eventually decreases 1070. These features of transconductance are explainable from basic MOSFET theory, as explained for example, in Sze (S. M. Sze, “Physics of Semiconductor Devices”, 1981, pp. 449). Transconductance gₘ is defined as:

$${{g}_{m} = \frac{\partial {I}_{d}}{\partial {V}_{g}} \vert}_{{V}_{d} = const} ∼ \overline{μ} \qquad ( 3 )$$

and is proportional to the effective mobile charge carrier mobility \overline{μ}. Initially as V_{g} increases, the total charge in the inversion layer, or more generally the channel region, increases and gₘ increases. However, as V_{g} continues to increase, the transverse electric field (the electric field perpendicular to current flow) also increases, which causes the effective carrier mobility \overline{μ} to decrease, as shown by Sze. The increased transverse electric field pulls mobile charge carrier towards the gate insulator interface to the channel region, thereby increasing scattering of the mobile charge carriers with the gate insulator interface to the channel region and reducing the effective carrier mobility \overline{μ}. Eventually, the decrease in mobility counteracts the addition of charge, gₘ reaches a maximum, saturates, and then decreases as the transverse electric field increases with increasing V_{g}. For this reason, as is known in the art, f_{T} is typically reported at a maximum gₘ, which is usually at a V_{g} significantly less than V_{dd}. See for example Kuhn, et. al. (K. Kuhn et al., 2004 Symposium on VLSI Technology Digest of Technical Papers, 2004, pp. 224, 225), where f_{T} is measured at V_{ds}=1.2V and V_{gs}=0.7V.

This is to be contrasted to the gₘ characteristic curve 1030 shown in FIG. 10 for a fabricated SB-PMOS device. Here, the gₘ curve 1030 increases, reaches a maximum, and then remains generally flat, even up to the voltage V_{g} of −1.6V. The measured gₘ at V_{dd}=−1.2V (528 mS/mm) is 97.2% of the maximum gₘ (543 mS/mm) measured at V_{g}=−1.55V. As explained in the present teachings, the SB-PMOS device provides substantial bulk charge transport, which means significantly less carriers interact with and scatter off of the gate insulator interface to the channel region, making the effective carrier mobility \overline{μ} less sensitive to increases in the transverse electric field until very high gate biases V_{g}.

In summary, the SB-MOS transconductance gₘ is at least 90% of the maximum transconductance when the gate voltage V_{g} is equal to the supply voltage, V_{dd}. As a further example, the SB-MOS transconductance gₘ is at least 60% of the maximum transconductance when the gate voltage V_{g} is equal to the supply voltage, V_{dd}. More generally, the SB-MOS transconductance gₘ is approximately equal to the maximum transconductance when the gate voltage V_{g} is equal to the supply voltage, V_{dd}. The gₘ measurements of the present teachings provide additional experimental support of the conclusion that SB-MOS devices as utilized in the present invention provide substantial bulk charge transport.

From the measurements of f_{T} and gₘ, it is possible to estimate the gate capacitance C_{g} using equation 2 for f_{T} shown above.

$${C}_{g , {f}_{T}} = \frac{{g}_{m}}{2 π {f}_{T}} \qquad ( 4 )$$

Furthermore, for the geometry of the devices fabricated, it is possible to calculate the ideal total gate capacitance C_{g,tot,ideal}. C_{g,tot,ideal} is the ideal total gate capacitance based on classical MOSFET device theory, and is provided by the following expression:
C_{g,tot,ideal}=C_{g,ideal}+2*C_{F} (5)
where C_{F} is the parasitic fringing-field gate capacitance per side (W. Liu, MOSFET Models for SPICE Simulation including BSIM3vs and BSIM4, 2001, pp. 176-177):

$${C}_{F} = \frac{2 {ɛ}_{ox}}{π} [ ln ( 1 + \frac{{T}_{poly}}{{T}_{ox}} ) + ln \frac{π}{2} + 0.308 ] \qquad ( 6 )$$

where εₒₓ is the permittivity of the oxide, T_{poly} is the thickness of the poly-silicon gate with T_{poly}=115 nm, and Tₒₓ is the thickness of the gate insulator with Tₒₓ=1.8 nm. C_{g,ideal} is the capacitance due to an ideal MOS structure and is given by,

$${C}_{g , ideal} = \frac{{ɛ}_{ox}}{{EOT}_{inv}} {L}_{g} \qquad ( 7 )$$

where EOT_{inv=T}ₒₓ+0.4 nm, where 0.4 nm is due to the inversion layer effects, including quantum effects (C. International Technology Roadmap for Semiconductors 2003 Edition Process Integration Devices and Structures, 2003, pp. 11-13) and L_{g} is the gate length and is 25, 55, or 75 nm. As can be seen from Table 1, the gate capacitance for the measured SB-PMOS devices with substantial bulk charge transport is approximately two to three times (2-3×) lower than the ideal total gate capacitance, which is consistent with the teachings above that show various SB-PMOS devices provide a factor of 2.05-2.54 higher f_{T} as compared to equivalent L_{g} conventional PMOS device data.

TABLE 1

| | | | | | | | Ratio of |
|---|---|---|---|---|---|---|---|
| L_{g} | V_{d} | V_{g} | Gₘ | f_{T} | C_{g,fT} | C_{g,tot,ideal} | C_{g,tot,ideal} to |
| (nm) | (V) | (V) | (S) | (GHz) | (C) | (C) | C_{g,fT} |
| 25 | 1.1 | 2.9 | 334 | 232 | 0.23 | 0.61 | 2.66 |
| 55 | 1.1 | 2.9 | 532 | 164 | 0.52 | 1.08 | 2.09 |
| 75 | 1.35 | 2.75 | 548 | 157 | 0.56 | 1.39 | 2.50 |

In summary, as one example, an SB-MOS device C_{g,f}_{T} is less than or equal to 75% of the ideal total gate capacitance C_{g,tot,ideal}. As another example, an SB-MOS device C_{g,f}_{T} is less than or equal to 50% of the ideal total gate capacitance C_{g,tot,ideal}. As another example, an SB-MOS device C_{g,f}_{T} is less than or equal to 33% of the ideal total gate capacitance C_{g,tot,ideal}. More generally, an SB-MOS device C_{g,f}_{T} is substantially less than the ideal total gate capacitance C_{g,tot,ideal}. The C_{g,f}_{T} data of the present teachings provides additional experimental support of the conclusion that SB-MOS devices as utilized in the present invention provide substantial bulk charge transport.

In summary of the present teachings, Monte Carlo device simulation show that mobile charge carriers transport from source to drain substantially in the bulk semiconductor substrate. This conclusion is supported by three experimental results from fabricated SB-PMOS devices: Very high f_{T} measurements that are a factor of approximately 2 to 4 times greater than data for conventional PMOS devices; SB-PMOS gₘ measurements showing very little decrease in gₘ at high V_{g}, and SB-PMOS C_{g,ff} data that is approximately 50% lower than the expected ideal total gate capacitance calculated from classical theory.

The substantial bulk charge transport characteristic of the SB-MOS device of the present invention also affects other properties of the device, which may significantly enhance device and integrated circuit performance. As noted, substantial bulk charge transport means a substantial number of charge carriers flow in the bulk silicon rather than in a very thin layer just below the gate insulator. As such, this charge is less susceptible to gate insulator interface surface scattering and columbic scattering, which enables significantly improved effective carrier mobility \overline{μ} in the channel region for the charge carriers and help with integration of high K gate insulators. Furthermore, less interaction of the charge carriers in the channel region with the gate insulator reduces the noise characteristics of the device, such as 1/f flicker noise and noise figure. It further improves the gate insulator reliability and reduces the hot carrier effect therefore improving the device and circuit lifetime of useful operation. It is also possible that for certain conditions of operation in an IC circuit, the device will have less gate leakage due to the substantial bulk charge transport. These features will provide improved performance in an integrated circuit in terms of switching speed, noise, power and reliability.

The present invention teaches an integrated circuit having at least one SB-PMOS device or at least one SB-NMOS device having substantial bulk charge transport. The present teachings show that substantial bulk transport provides improved channel mobility and gate capacitance, thereby counteracting the effects of the SB-MOS sub-linear turn-on characteristic and providing improved IC performance. The present invention is particularly suitable for use in situations where short channel length MOSFETs are to be fabricated, especially in the range of channel lengths less than 500 run. However, nothing in the teachings of the present invention limits application of the teachings of the present invention to these short channel length devices.

Although the present invention has been described with reference to preferred embodiments, persons skilled in the art will recognize that changes may be made in form and detail without departing from the spirit and scope of the invention. The present invention applies to any use of metal source drain technology, whether it employs SOI substrate, strained Silicon substrate, SiGe substrate, FinFET technology, high K gate insulators, and metal gates. This list is not limitive. Any device for regulating the flow of electric current that employs metal source-drain contacts used in an IC will have the benefits taught herein.

1. An integrated circuit, the integrated circuit comprising:
at least one NMOS device or PMOS device;
wherein at least one of the NMOS devices or PMOS devices is a Schottky barrier MOS device with substantial bulk charge transport.

2. The integrated circuit of claim 1 wherein at least one of the NMOS device and PMOS device exhibits C_{g,fr} of less than or equal to 75% of C_{g tot, ideal}.

3. The integrated circuit of claim 1 wherein at least one of the NMOS device and PMOS device exhibit transconductance of at least 90% of the maximum transconductance when gate voltage V_{g} is equal to supply voltage, V_{dd}.

4. The integrated circuit of claim 1 wherein at least one of the NMOS device and PMOS device is a Schottky barrier device comprising:
a semiconductor substrate;
a gate electrode on the semiconductor substrate;
a source electrode and a drain electrode on the semiconductor substrate defining a channel region having a channel-length and having mobile charge carriers, wherein at least one of the source electrode and drain electrode forms a Schottky or Schottky-like contact to the substrate.

5. The integrated circuit of claim 4 wherein the semiconductor substrate is comprised of silicon, strained silicon, silicon on insulator, silicon germanium, gallium arsenide, or indium phosphide.

6. The integrated circuit of claim 4 wherein the source electrode and the drain electrode of the Schottky barrier PMOS device are formed of any one or combination of Platinum Silicide, Palladium Silicide or Iridium Silicide.

7. The integrated circuit of claim 4 wherein the source electrode and the drain electrode of the Schottky barrier NMOS device are formed of rare-earth silicides.

8. The integrated circuit of claim 4 wherein at least one of the source and drain electrodes of the Schottky barrier PMOS devices or Schottky barrier NMOS devices forms a Schottky or Schottky-like contact with the semiconductor substrate at least in areas adjacent to the channel.

9. The integrated circuit of claim 4 wherein an entire interface between at least one of the source and the drain electrodes of the Schottky barrier PMOS devices or Schottky barrier NMOS devices and the semiconductor substrate forms a Schottky contact or Schottky-like region with the semiconductor substrate.

10. The integrated circuit of claim 4 wherein the channel contains channel dopants in the semiconductor substrate.

11. The integrated circuit of claim 10 wherein the channel dopant concentration varies in a vertical direction of the semiconductor substrate and is substantially constant in a lateral direction in the semiconductor substrate.

12. The integrated circuit of claim 10 wherein the channel dopant concentration varies in a vertical direction and a lateral direction in the semiconductor substrate.

13. The integrated circuit of claim 10 wherein the channel dopants for the Schottky barrier PMOS device comprises Arsenic, Phosphorous, Antimony or any combination thereof.

14. The integrated circuit of claim 10 wherein the channel dopants for the Schottky barrier NMOS device comprises Boron, Indium, Gallium or any combination thereof.

15. The integrated circuit of claim 4 wherein the gate electrode of the Schottky barrier PMOS devices or Schottky barrier NMOS devices has a length not exceeding 500 nm.

16. The integrated circuit of claim 4 wherein the gate electrode of at least one of the Schottky barrier NMOS or Schottky barrier PMOS devices comprises:
an insulating layer on the semiconductor substrate;
a conducting film on the insulating layer; and
at least one insulating layer on at least one sidewall of the conducting film.

17. The integrated circuit of claim 16 wherein the mobile charge carriers are substantially removed from the interface of the insulating layer and the semiconductor substrate.

18. The integrated circuit of claim 16 wherein the interaction of the mobile charge carriers with the interface of the insulating layer and the semiconductor substrate is substantially reduced.

19. The integrated circuit of claim 16 wherein the Schottky barrier NMOS device has a gate electrode conducting film comprised of phosphorous doped polysilicon.

20. The integrated circuit of claim 16 wherein the Schottky barrier PMOS device has a gate electrode conducting film comprised of boron doped polysilicon.

21. The integrated circuit of claim 16 wherein the Schottky barrier NMOS device has a metal gate electrode conducting film.

22. The integrated circuit of claim 16 wherein the Schottky barrier PMOS device has a metal gate electrode conducting film.

23. The integrated circuit of claim 16 wherein the insulating layer on the semiconductor substrate is silicon dioxide.

24. The integrated circuit of claim 16 wherein the insulating layer on the semiconductor substrate is a high k dielectric formed from a member comprised of nitrided silicon dioxide, silicon nitride, metal oxides, or any combination thereof.

25. The integrated circuit of claim 1, wherein the device further comprises at least one NMOS device or PMOS device having an impurity doped source and drain electrode electrically connected to a Schottky barrier NMOS or Schottky barrier PMOS device.

26. A CMOS circuit, the CMOS circuit, comprising:
at least one Schottky barrier NMOS device;
at least one Schottky barrier PMOS device, electrically connected to at least one Schottky barrier NMOS device;
wherein at least one of the Schottky barrier NMOS devices or the Schottky barrier PMOS devices provides substantial bulk transport.

27. The CMOS circuit of claim 26 wherein at least one of the Schottky barrier NMOS device and Schottky barrier PMOS device exhibits C_{g,f}_{T} of less than or equal to 75% of C_{g tot, ideal}.

28. The CMOS circuit of claim 26 wherein at least one of the Schottky barrier NMOS device and Schottky barrier PMOS device exhibit transconductance of at least 90% of the maximum transconductance when gate voltage V_{g} is equal to supply voltage, V_{dd}.

29. The CMOS circuit of claim 26 wherein the Schottky barrier NMOS and Schottky barrier PMOS devices each comprises:
a semiconductor substrate;
a gate electrode on the semiconductor substrate;
a source electrode and a drain electrode on the semiconductor substrate defining a channel region having a channel-length and having mobile charge carriers, wherein at least one of the source electrode and drain electrode forms a Schottky or Schottky-like contact to the substrate.

30. The CMOS circuit of claim 29 wherein the semiconductor substrate is comprised of silicon, strained silicon, silicon on insulator, silicon germanium, gallium arsenide, or indium phosphide.

31. The CMOS circuit of claim 29 wherein the source electrode and the drain electrode of the Schottky barrier PMOS device are formed from a member comprised of Platinum Silicide, Palladium Silicide or Iridium Silicide.

32. The CMOS circuit of claim 29 wherein the source electrode and the drain electrode of the Schottky barrier NMOS device are formed from a member comprised of rare-earth silicides.

33. The CMOS circuit of claim 29 wherein at least one of the source and drain electrodes of the Schottky barrier PMOS devices or Schottky barrier NMOS devices forms a Schottky or Schottky-like contact with the semiconductor substrate at least in areas adjacent to the channel.

34. The CMOS circuit of claim 29 wherein an entire interface between at least one of the source and the drain electrodes of the Schottky barrier PMOS devices or Schottky barrier NMOS devices and the semiconductor substrate forms a Schottky contact or Schottky-like region with the semiconductor substrate.

35. The CMOS circuit of claim 35 wherein the channel contains channel dopants in the semiconductor substrate.

36. The CMOS circuit of claim 35 wherein the channel dopant concentration varies in a vertical direction of the semiconductor substrate and is substantially constant in a lateral direction in the semiconductor substrate.

37. The CMOS circuit of claim 35 wherein the channel dopant concentration varies in a vertical direction and a lateral direction in the semiconductor substrate.

38. The CMOS circuit of claim 35 wherein the channel dopants for the Schottky barrier PMOS device comprises Arsenic, Phosphorous, Antimony or any combination thereof.

39. The CMOS circuit of claim 35 wherein the channel dopants for the Schottky barrier NMOS device comprises Boron, Indium, Gallium or any combination thereof.

40. The CMOS circuit of claim 29 wherein the gate electrode of the Schottky barrier PMOS devices or Schottky barrier NMOS devices has a length not exceeding 500 nm.

41. The CMOS circuit of claim 29 wherein the gate electrode of at least one of the Schottky barrier NMOS or Schottky barrier PMOS devices comprises:
an insulating layer on the semiconductor substrate;
a conducting film on the insulating layer; and
at least one insulating layer on at least one sidewall of the conducting film.

42. The CMOS circuit of claim 29 wherein the mobile charge carriers are substantially removed from the interface of the insulating layer and the semiconductor substrate.

43. The CMOS circuit of claim 29 wherein the interaction of the mobile charge carriers with the interface of the insulating layer and the semiconductor substrate is substantially reduced.

44. The CMOS circuit of claim 41 wherein the Schottky barrier NMOS device has a gate electrode conducting film comprised of phosphorous doped polysilicon.

45. The CMOS circuit of claim 41 wherein the Schottky barrier PMOS device has a gate electrode conducting film comprised of boron doped polysilicon.

46. The CMOS circuit of claim 41 wherein the Schottky barrier NMOS device has a metal gate electrode conducting film.

47. The CMOS circuit of claim 41 wherein the Schottky barrier PMOS device has a metal gate electrode conducting film.

48. The CMOS circuit of claim 41 wherein the insulating layer on the semiconductor substrate is silicon dioxide.

49. The CMOS circuit of claim 48 wherein the insulating layer on the semiconductor substrate is a high k dielectric formed from a member comprised of nitrided silicon dioxide, silicon nitride, metal oxides, or any combination thereof.

50. The CMOS circuit of claim 26, wherein the device further comprises at least one NMOS device or PMOS device having an impurity doped source and drain electrode electrically connected to the Schottky barrier NMOS or Schottky barrier PMOS devices.
